(19) United States
(12) Patent Application Publication
(10) Pub. No.: US 2013/0105893 A1
(43) Pub. Date: May 2, 2013

(54) DMOS TRANSISTOR ON SOI

(71) Applicants: STMicroelectronics SA, Montrouge (FR); STMicroelectronics (Crolles 2) SAS, Crolles (FR)

(72) Inventors: David Petit, Grenoble (FR); Bruno Rauber, Goncelin (FR)

(73) Assignees: STMICROELECTRONICS (CROLLES 2) SAS, Crolles (FR); STMICROELECTRONICS SA, Montrouge (FR)

(21) Appl. No.: 13/660,681

(22) Filed: Oct. 25, 2012

(30) Foreign Application Priority Data
Oct. 26, 2011 (FR) 1159698

(51) Int. Cl. H01L 27/088; H01L 21/336

(52) U.S. Cl. 257/336; 438/155; 257/337; 257/E27.06; 257/E21.417

(57) ABSTRACT

A DMOS on SOI transistor including an elongated gate extending across the entire width of an active area; a drain region of a first conductivity type extending across the entire width of the active area; a source region of the first conductivity type extending parallel to the gate and stopping before the limit of the active area at least on one side of the transistor width, an interval existing between the limit of the source region and the limit of the active area; a bulk region of a second conductivity type extending under the gate and in said interval; a more heavily-doped region of the second conductivity type extending on a portion of said interval on the side of the limit of the active area; and an elongated source metallization extending across the entire width of the active area.

### BACKGROUND

1. Technical Field

The present disclosure relates to diffused metal oxide semiconductor DMOS transistors, which are often used in integrated circuits to withstand and switch higher voltages than those implied in the switching of complementary metal oxide semiconductor (CMOS) logic transistors.

2. Description of the Related Art

FIGS. 1A, 1B, and 1C respectively are a top view, a cross-section view along plane BB of FIG. 1A, and a cross-section view along plane CC of FIG. 1A of an example of a DMOS transistor.

More specifically, these drawings show a P-channel DMOS transistor formed in a thin silicon layer laid on an insulator, generally itself formed on a silicon wafer, according to a structure currently designated as SOI (Silicon On Insulator). The shown DMOS transistor is of so-called extended drain type, that is, the heavily-doped drain contact region 19 is distant from the limit of the channel region 10 and there exists a drain region, currently called drift region 5, which is more lightly doped between the drain contact region and the limit of the channel region, thus helping increasing the breakdown voltage of the device. Further, FIGS. 1A to 1C illustrate a symmetrical device comprising a gate and a drain on each side of a central source strip.

In the top view of FIG. 1A, the top view of the structure without the gate and without the drain and source metallizations has been shown on the left-hand side of an axis of symmetry CC, and the gate and the drain and source metallizations have been shown on the right-hand side of axis of symmetry CC.

As more specifically shown in the cross-section view of FIG. 1B, the structure is formed in an active silicon area formed above a support 1 coated with an insulating layer 2 and delimited by an insulating region 3 which joins insulating layer 2. For simplification, this structure will be described in relation with its manufacturing steps.

The active area delimited by insulating region 3 is a portion of a lightly-doped silicon layer 5, of type P in the case which will described hereafter of the forming of a P-channel transistor.

Above the surface of the active layer are formed symmetrical gates extending along the entire length of the active area. Each gate comprises a polysilicon strip 7 insulated from the underlying semiconductor by a thin insulating layer 6. An N-type region 10 is formed by diffusion from the interval between the two gates, the rest of the structure being masked. This N-type region 10 extends under a portion of the length of each gate to form the transistor bulk (the region in which a channel is likely to form when the gate is properly biased). A lightly-doped P-type surface region 12 is then formed, from the interval between the two gates. After this, spacers 14 are formed on either side of each gate and a protection layer 16 is formed towards the outside with respect to the gates to delimit above-mentioned drift region 5, and a P-type dopant is implanted. A P⁺-type central source region 18 and drain contact regions 19 are thus formed (to the right and to the left in FIGS. 1A and 1B). Once this structure has been obtained, a siliciding, which is automatically performed on all exposed single-crystal or polysilicon surfaces, is carried out. Thus, a source silicide region MS forms above source 18, gate silicide regions MG form above gates 7, and drain silicide regions MD form above drain contact regions 19, drift region 5 being protected from this siliciding.

The foregoing description can be more specifically read from the representation of FIGS. 1A and 1B. However, in addition to the drain, source, and gate metallizations, bulk region 10 should further be contacted to be able to be biased to the same voltage as source region 18. The way in which this contact is obtained is more clearly shown in FIGS. 1A and 1C. As shown in these drawings, the diffusion of source region 12-18 is not performed across the entire transistor width but is interrupted by masking at a given distance, d, from the limit of the active area. It should be understood that the views of FIGS. 1A and 1C are partial and that the above-mentioned interruption is actually preferably carried out on both sides of the structure.

In the interval corresponding to distance d, a heavily-doped N-type region 20 is formed. In the siliciding step, region 20 is covered with the same silicide layer MS as the entire source region. Thus, this N⁺ region, which contacts region 10, is biased in operation to the same voltage as the source (the high voltage reference in the described case of a P-channel DMOS transistor).

The above-described device operates satisfactorily. However, it exhibits a leakage current when it is in the off state.

### BRIEF SUMMARY

An embodiment provides a DMOS transistor of the previously-described type having a decreased off-state leakage current.

An embodiment provides a DMOS on SOI transistor comprising an elongated gate extending across the entire width of an active area; a drain region of a first conductivity type extending across the entire width of the active area; a source region of the first conductivity type extending parallel to the gate and stopping before the limit of the active area at least on one side of the transistor width, an interval existing between the limit of the source region and the limit of the active area; a bulk region of a second conductivity type extending under the gate and in said interval; a more heavily-doped region of the second conductivity type extending on a portion of said interval on the side of the limit of the active area; and an elongated source metallization extending across the entire width of the active area.

According to an embodiment, the source is arranged in central fashion and a gate strip is provided on each side of the source.

According to an embodiment, the drain region comprises a more lightly-doped strip on the gate side and a more heavily-doped strip on the side of the limit of the active area.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIGS. 1A to 1C, previously described, are a partial top view, a cross-section view along line BB of FIG. 1A, and a partial cross-section view along line CC of FIG. 1A; and

FIGS. 2A to 2C are a partial top view, a cross-section view along line BB of FIG. 2A, and a partial cross-section view along line CC of FIG. 2A.

As usual in the representation of integrated circuits, the various drawings are not to scale.

### DETAILED DESCRIPTION

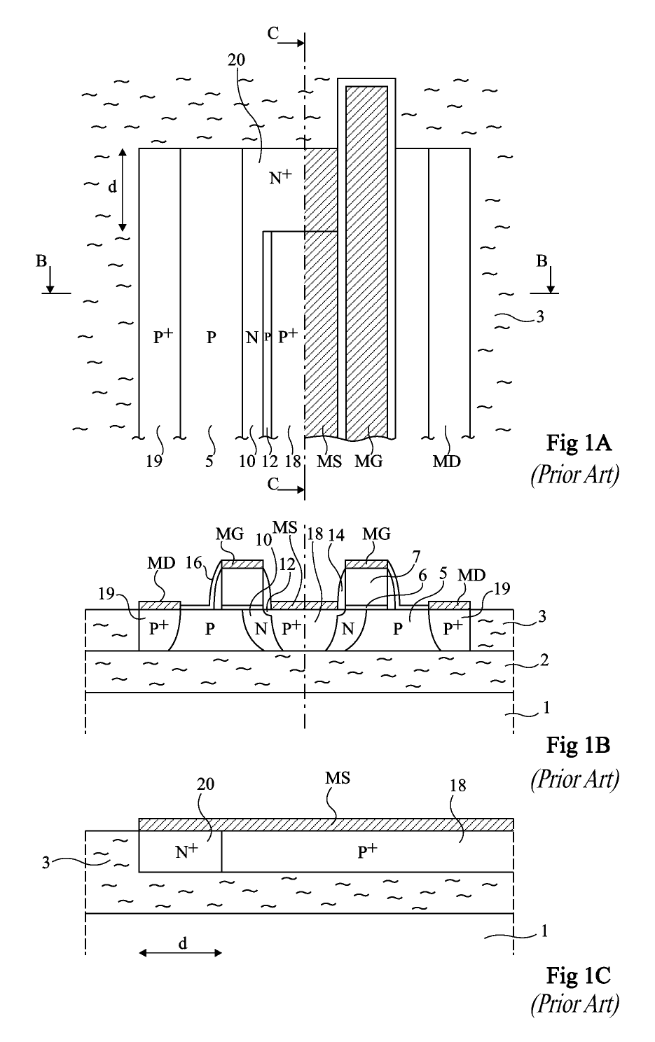

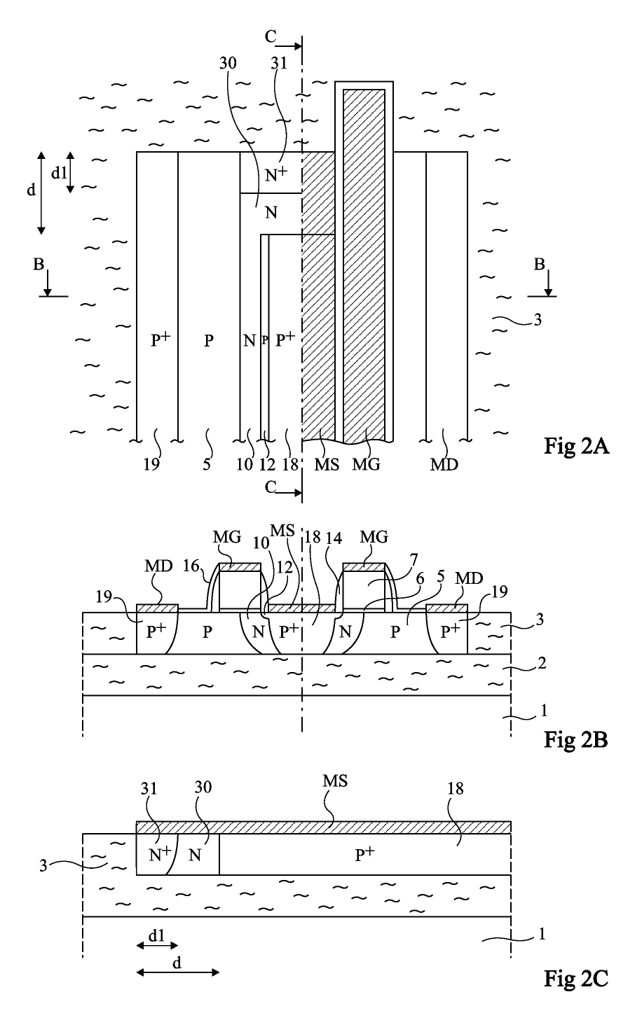

FIGS. 2A, 2B, and 2C are views of a DMOS-on-SOI transistor and respectively correspond to FIGS. 1A, 1B, and 1C describing the state of the art.

FIG. 2B (cross-section BB of the top view of FIG. 2A) is strictly identical to previously-described FIG. 1B and the same elements are designated with the same reference numerals. The embodiment of FIGS. 2A and 2C differs from FIGS. 1A and 1C by the contacting mode on bulk 10 of the transistor. Only the differences between FIGS. 2A and 2C and FIGS. 1A and 1C will be highlighted hereafter.

Previously-described distance d between the limit of the active area and the widthwise interruption of the source layer in practice should not be decreased, since a minimum guard distance should be kept between a P-type diffused region and the limit of the active area to be sure that a sufficiently extended N-type exposed area remains in place.

However, the present inventors have noted that the extension of the N⁺-type bulk contact region could be limited. Thus, FIGS. 2A and 2B show that P-type source layer 18 and P-type layer 12 are interrupted as previously at a distance d from the limit of the active area to expose an N-type doped region 30 corresponding to bulk region 10.

In the embodiment of FIGS. 2A to 2C, an N⁺-type contact region 31 extends across a width smaller than value d, that is, only across a width dl from the limit of the active area. Indeed, even if there is an error percentage on the value of d1 due to manufacturing uncertainties, there will always remain an exposed portion of N⁺ region 31 and N region 30. Then, source metallization (silicidation) MS will make a contact with P⁺ region 18, and with regions 30 and 31. The contact on region 31 is an ohmic contact and, even if the contact with region 30 is not perfect, there will still remain a contact which will enable to bias region 30 and, via said region, bulk region 10. Indeed, since N layer 10, 30 has a relatively high doping level (5.10¹⁷ to 10¹⁸ at./cm³), the contact with this region 30 remains satisfactory.

Tests have been carried out on a structure of the type of that in FIGS. 2A to 2C, which had the following characteristics:
total width of the active area greater than 5 μm,
total length, from the external limit of the drain region to the external limit of the symmetrical drain region, approximately ranging from 2.5 to 3 μm,
gate length on the order of 0.4 μm,
distance between gates on the order of 1 μm,
distance between the external edges of the gates and the limits of the drain contact regions on the order of 0.5 μm,
doping of drift regions 5 on the order of 10¹⁷ atoms per cm³,
doping of N bulk region 10, on the order of 10¹⁸ at./cm³,
doping of N⁺ bulk region 31 on the order of 10²⁰ at./cm³,
value of distance d on the order of 0.4 μm,
value of distance d1 approximately d/2.

An off-state leakage current smaller than 100 pA/μm has been observed with such a structure while, for a device such as that of FIGS. 1A to 1C of same dimensions and for the same value of d, this leakage current was at least double (greater than 200 pA/μm). This allows to think that one of the main leakage current sources in the structure of FIGS. 1A-1C was junction N⁺P between the bulk contact region and drift region 5.

Of course, many alterations, modifications, and improvements will occur to those skilled in the art, especially as concerns the forming of the DMOS transistor. In particular, bulk region 10 has been shown as extending under a small portion (approximately half) of the gate length. This extension may in practice be variable. Similarly, variable lengths of drift areas 5 between the bulk region and the drain contact region may be provided. Finally, a transistor symmetrical with respect to a central source region has been described. It may be provided for the device to only substantially comprise what is shown in the right-hand or left-hand portion of FIG. 2A.

Further, the case of a P-channel transistor has been described in the foregoing. The present disclosure will similarly apply to an N-channel transistor.

Such alterations, modifications, and improvements are intended to be part of this disclosure, and are intended to be within the spirit and the scope of the present disclosure. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A DMOS transistor structure, comprising:
an elongated first gate extending longitudinally across an entire width of an active area of a semiconductor substrate, the active area having a limit defining one side of the entire width;
a drain region of a first conductivity type extending longitudinally across the entire width of the active area;
a source region of the first conductivity type extending in the active area and parallel to the first gate and stopping before the limit of the active area, a limit of the source region being spaced apart from the limit of the active area by an interval;
a bulk region of a second conductivity type extending under the first gate and in said interval;
a more heavily-doped region of the second conductivity type extending in a portion of said interval on the side of the limit of the active area; and
an elongated conductive source contact extending across the entire width of the active area.

2. The DMOS transistor structure of claim 1, wherein the source region is positioned centrally in the active area, the DMOS transistor structure including a second gate positioned on an opposite side of the source region compared to the first gate, the first and second gates being parts of first and second DMOS transistors, respectively.

3. The DMOS transistor structure of claim 1, wherein the drain region comprises a more lightly-doped strip adjacent to the first gate and a more heavily-doped strip adjacent to the limit of the active area.

4. The DMOS transistor structure of claim 1, wherein the substrate is a silicon-on-insulator substrate.

5. A DMOS transistor structure, comprising:
an elongated first gate extending longitudinally across an active area of a semiconductor substrate, the active area having a lateral limit;
a first region of a first conductivity type extending longitudinally across the active area;
a second region of the first conductivity type extending in the active area, a lateral limit of the second region being spaced apart from the lateral limit of the active area by an interval;
a bulk region of a second conductivity type extending under the first gate and in said interval;
a more heavily-doped region of the second conductivity type extending in a portion of said interval, the bulk region being positioned between the more heavily-doped region and the second region; and
an elongated conductive contact extending across the active area and contacting upper surfaces of the second region, bulk region, and more heavily-doped region.

6. The DMOS transistor structure of claim 5, wherein the second region is positioned centrally in the active area, the DMOS transistor structure including a second gate positioned on an opposite side of the second region compared to the first gate, the first and second gates being parts of first and second DMOS transistors, respectively.

7. The DMOS transistor structure of claim 5, wherein the first region comprises a more lightly-doped strip adjacent to the first gate and a more heavily-doped strip adjacent to the lateral limit of the active area.

8. The DMOS transistor structure of claim 5, wherein the substrate is a silicon-on-insulator substrate.

9. The DMOS transistor structure of claim 5, wherein the first region is a drain region and the second region is a source region

10. The DMOS transistor structure of claim 5, wherein the first region and the elongated conductive contact extend to the lateral limit of the active area and the first gate extends at least to the lateral limit of the active area.

11. A method of making DMOS transistor structure, comprising:
forming an elongated first gate extending longitudinally across an active area of a semiconductor substrate, the active area having a lateral limit;
forming a first region of a first conductivity type extending longitudinally across the active area;
forming a second region of the first conductivity type extending in the active area, a lateral limit of the second region being spaced apart from the lateral limit of the active area by an interval;
forming a bulk region of a second conductivity type extending under the first gate and in said interval;
forming a more heavily-doped region of the second conductivity type extending in a portion of said interval, the bulk region being positioned between the more heavily-doped region and the second region; and
forming an elongated conductive contact extending across the active area and contacting upper surfaces of the second region, bulk region, and more heavily-doped region.

12. The method of claim 11, wherein forming the second region includes positioning the second region centrally in the active area, the method including forming a second gate positioned on an opposite side of the second region compared to the first gate, the first and second gates being parts of first and second DMOS transistors, respectively.

13. The method of claim 11, wherein forming the first region comprises forming a more lightly-doped strip adjacent to the first gate and forming a more heavily-doped strip adjacent to the lateral limit of the active area.

14. The method of claim 11, wherein the substrate is a silicon-on-insulator substrate.

15. The method of claim 11, wherein the first region is a drain region and the second region is a source region

16. The method of claim 11, wherein the first region and the elongated conductive contact extend to the lateral limit of the active area and the first gate extends at least to the lateral limit of the active area.
